(19) United States
(12) Patent Application Publication
(10) Pub. No.: US 2026/0097782 A1
(43) Pub. Date: Apr. 9, 2026

(54) SYSTEMS AND METHODS FOR TRAINING A LEARNING MODEL USING LABELED DATA GENERATED WITH AN ASSISTING OPERATOR FOR A TASK

(71) Applicant: Toyota Research Institute, Inc., Los Altos, CA (US)

(72) Inventors: Jonathan A. DeCastro, Arlington, MA (US); Emily Sarah Sumner, Cambridge, MA (US); Deepak Edakkattil Gopinath, Washington, DC (US); Andrew Michael Silva, Cambridge, MA (US); Thomas M. Balch, Damariscotta, ME (US); Xiongyi Cui, Somerville, MA (US); Guy Rosman, Cambridge, MA (US)

(73) Assignees: Toyota Research Institute, Inc., Los Altos, CA (US); Toyota Jidosha Kabushiki Kaisha, Toyota-shi Aichi-ken (JP)

(21) Appl. No.: 18/905,603

(22) Filed: Oct. 3, 2024

(51) Int. Cl. B60W 60/00; B60W 10/04; B60W 10/18; B60W 10/20; B60W 50/16; G06F 30/27

(52) U.S. Cl. CPC B60W 60/001; B60W 10/04; B60W 10/18; B60W 10/20; B60W 50/16; G06F 30/27

(57) ABSTRACT

Systems, methods, and other embodiments described herein relate to training a learning model using labeled data generated through a suggestion from an assisting operator to another operator for executing a task. In one embodiment, a method includes acquiring a driving suggestion from an assisting operator associated with a driving scenario involving a vehicle. The method also includes receiving a driving command and vocal data from the vehicle about following the driving suggestion during the driving scenario. The method also includes training a shared-driving model using the driving suggestion, the driving command, and the vocal data.

### TECHNICAL FIELD

The subject matter described herein relates, in general, to training a learning model for a task, and, more particularly, to training the learning model using labeled data generated through a suggestion from an assisting operator to another operator for executing the task.

### BACKGROUND

A learning model is a computational framework that learns from data to make predictions and decisions about a task. Learning can involve changing parameters that are adjustable using patterns and features about the data for improving accuracy over time involving the task. For example, a vehicle acquires image data from cameras for a learning model to perceive obstacles in a surrounding environment using the image data. Improving perceptions of the surrounding environment and detecting obstacles allows downstream tasks by systems such as automated driving systems (ADS) to plan and navigate a road. As such, a vehicle can follow a trajectory outputted from the ADS with increased reliability by detecting obstacles using the learning model.

In various implementations, systems train the learning model for estimating task variables involving a task with training data encompassing potential data inputs. The learning model can train through adjusting parameters by minimizing a loss that represents a difference between predicted values and actual values. For example, the system iteratively updates the parameters using feedback about the training data given by a human observer that rates the predicted values. However, systems encounter difficulties acquiring training data that describes diverse and varying events in detail. Thus, training a learning model to estimate parameters for a task can be hindered by training data that is limited, thereby reducing prediction accuracy and robustness.

### SUMMARY

In one embodiment, example systems and methods relate to training a learning model using labeled data generated through a suggestion from an assisting operator to another operator for executing a task. In various implementations, systems training learning models rely upon having training data derived from various scenarios and inputs. However, acquiring complete and detailed data about various scenarios associated with prediction tasks faces challenges. For instance, a learning model estimating trajectories for an automated driving system (ADS) trains with data that lacks labels for events involving an animal crossing during a storm. As such, a vehicle following driving commands (e.g., an acceleration command) from the ADS during the storm can collide with the animal from a data gap representing the scenario when training the learning model. In other words, the learning model does not train for the driving scenario due to the data gap, thereby creating a hazardous event and reducing system reliability.

Therefore, in one embodiment, an assistance system communicates labeled data collected while an assisting operator supplies suggestions for a vehicle to follow during a scenario having a task. Here, the task can be a driving maneuver that is typical, atypical, complex, etc. A learning model (e.g., a shared-driving model) can train to improve predictions with the collected data having labels that are detailed and diverse with limited manual input. For instance, the system captures and labels data during simulated driving where the assisting operator (e.g., an advanced driver) supplies a driving command and a vocal command for a scenario having a sharp curve that improves safety and performance. Furthermore, the assistance system having inputs from an assisting operator naturally embeds supervision into the labeled data with minimal costs. In this way, the assistance system allows the learning model to generate predictions exhibiting increased accuracy through training with the labeled data that encompasses typical and vast interactions between human-to-human, human-to-robot, etc., tasks.

In one embodiment, an assistance system for training a learning model using labeled data generated through a suggestion from an assisting operator to another operator for executing a task is disclosed. The assistance system includes a memory including instructions that, when executed by a processor, cause the processor to acquire a driving suggestion from an assisting operator associated with a driving scenario involving a vehicle. The instructions also include instructions to receive a driving command and vocal data from the vehicle about following the driving suggestion during the driving scenario. The instructions also include instructions to train a shared-driving model using the driving suggestion, the driving command, and the vocal data.

In one embodiment, a non-transitory computer-readable medium for training a learning model using labeled data generated through a suggestion from an assisting operator to another operator for executing a task and including instructions that when executed by a processor cause the processor to perform one or more functions is disclosed. The instructions include instructions to acquire a driving suggestion from an assisting operator associated with a driving scenario involving a vehicle. The instructions also include instructions to receive a driving command and vocal data from the vehicle about following the driving suggestion during the driving scenario. The instructions also include instructions to train a shared-driving model using the driving suggestion, the driving command, and the vocal data.

In one embodiment, a method for training a learning model using labeled data generated through a suggestion from an assisting operator to another operator for executing a task is disclosed. In one embodiment, the method includes acquiring a driving suggestion from an assisting operator associated with a driving scenario involving a vehicle. The method also includes receiving a driving command and vocal data from the vehicle about following the driving suggestion during the driving scenario. The method also includes training a shared-driving model using the driving suggestion, the driving command, and the vocal data.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one embodiment of a vehicle within which systems and methods disclosed herein may be implemented.

FIG. 2 illustrates one embodiment of an estimation system that is associated with training a learning model using labeled data generated through a suggestion from an assisting operator to an operator for executing a task.

FIG. 3 illustrates one embodiment of the assistance system of FIG. 2 having an assisting operator supplying a driving suggestion for a vehicle to follow and generating a labeled dataset.

FIG. 4 illustrates an example of the assistance system implemented in a driving simulator for generating a labeled dataset and training data involving the assisting operator.

FIG. 5 illustrates one embodiment of a method that is associated with training a shared-driving model using the driving suggestion, a driving command, and vocal data captured by the labeled dataset.

### DETAILED DESCRIPTION

Systems, methods, and other embodiments associated with training a learning model using labeled data generated through a suggestion from an assisting operator to another operator for executing a task are disclosed herein. In various implementations, training a learning model to compute predictions that encompass diverse and evolving tasks faces challenges from incomplete and inaccurate datasets captured from vehicles. For instance, a driving dataset has mislabeled information about crossing a complex intersection involving multiple vehicles. As such, training a learning model with the driving dataset to estimate a vehicle trajectory for automatically navigating the complex interaction can involve erroneous outputs, thereby decreasing safety and confidence in automatic driving. Public datasets that are available may have limited data about certain human-to-human, human-to-robot, robot-to-robot, etc., interactions during tasks. Furthermore, systems using supervision and annotators to label data can increase costs and complexity for training learning models. Thus, systems can lack labeled data that comprehensively and efficiently captures varying events for training a learning model, thereby leading to less robust and reliable learning models.

Therefore, in one embodiment, an assistance system generates a labeled dataset automatically that involves an operator being assisted by another operator to complete a task through suggestions and a learning model trains using the labeled dataset. For instance, the assistance system receives a driving suggestion that is labeled made by an assisting operator for a vehicle to follow during a driving scenario. Here, the driving suggestion can be a steering command, a braking command, a voice command, etc., for an operator of the vehicle. Labeled data can include tokens (e.g., text, image segments, etc.) having categories (e.g., driving actions) as labels for a learning model to understand relationships and patterns during training and execute accurate predictions throughout inference from diverse inputs (e.g., vehicle direction). Furthermore, the assistance system receives a driving command and vocal data that are labeled representing actions taken by the operator following the driving suggestion. This allows a learning model to train by learning intricate execution details by the operator involving actions as influenced by the driving suggestion, thereby providing unique training insights. For example, the learning model operating as an automated driving system (ADS) in a shared driving environment encourages the operator to perform the actions, causes steering wheel manipulations, etc., for avoiding unsafe conditions. Therefore, the assistance system improves training of a learning model by efficiently capturing and labeling training data involving a task through an assisting operator supplying suggestions.

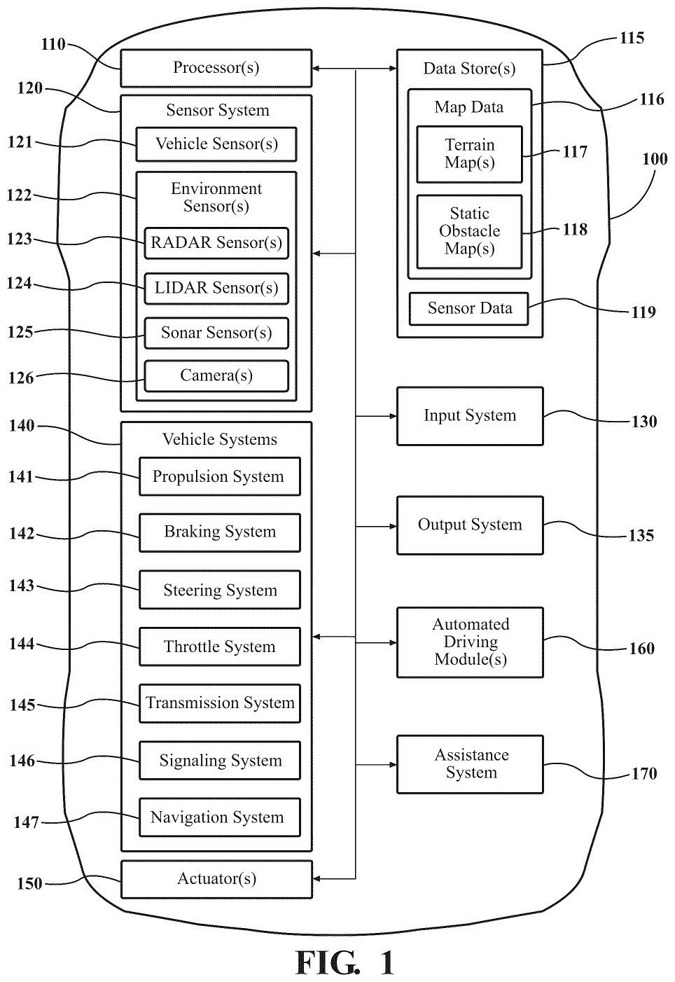

Referring to FIG. 1, an example of a vehicle 100 is illustrated. As used herein, a “vehicle” is any form of motorized transport. In one or more implementations, the vehicle 100 is an automobile. While arrangements will be described herein with respect to automobiles, it will be understood that embodiments are not limited to automobiles. For instance, the vehicle 100 is one of an automobile, a simulated vehicle, a virtual vehicle, a train, an airplane, and a boat that generates training data for the assistance system 170 to label. In some implementations, an assistance system 170 uses road-side units (RSU), consumer electronics (CE), mobile devices, robots, drones, and so on that benefit from the functionality discussed herein associated with training a learning model using labeled data generated through a suggestion from an assisting operator to another operator for executing a task.

The vehicle 100 also includes various elements. It will be understood that in various embodiments, the vehicle 100 may have less than the elements shown in FIG. 1. The vehicle 100 can have any combination of the various elements shown in FIG. 1. Furthermore, the vehicle 100 can have additional elements to those shown in FIG. 1. In some arrangements, the vehicle 100 may be implemented without one or more of the elements shown in FIG. 1. While the various elements are shown as being located within the vehicle 100 in FIG. 1, it will be understood that one or more of these elements can be located external to the vehicle 100. Furthermore, the elements shown may be physically separated by large distances. For example, as discussed, one or more components of the disclosed system can be implemented within a vehicle while further components of the system are implemented within a cloud-computing environment or other system that is remote from the vehicle 100.

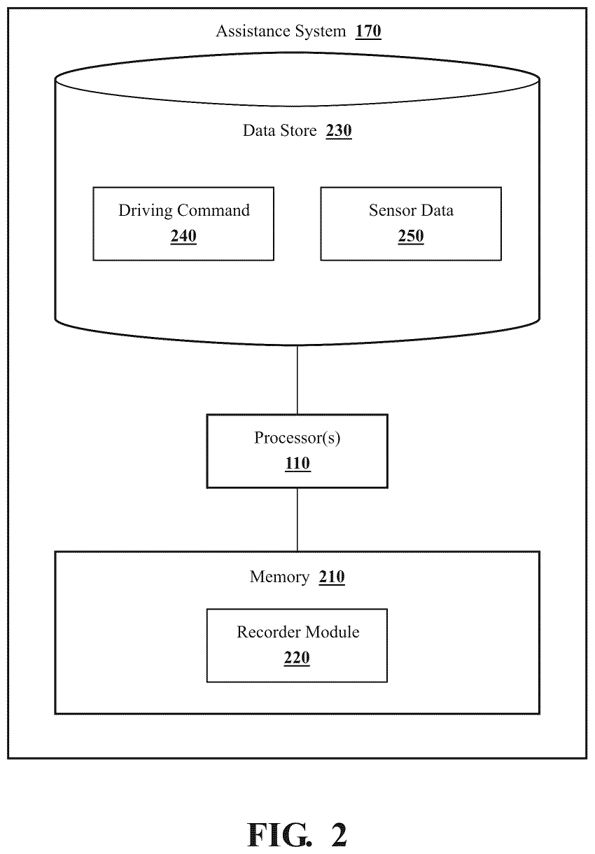

Some of the possible elements of the vehicle 100 are shown in FIG. 1 and will be described along with subsequent figures. However, a description of many of the elements in FIG. 1 will be provided after the discussion of FIGS. 2-5 for purposes of brevity of this description. Additionally, it will be appreciated that for simplicity and clarity of illustration, where appropriate, reference numerals have been repeated among the different figures to indicate corresponding or analogous elements. In addition, the discussion outlines numerous specific details to provide a thorough understanding of the embodiments described herein. Those of skill in the art, however, will understand that the embodiments described herein may be practiced using various combinations of these elements. In either case, the vehicle 100 includes an assistance system 170 that is implemented to perform methods and other functions as disclosed herein relating to improving training a learning model using labeled data generated through a suggestion from an assisting operator to another operator for executing a task.

As will be discussed in greater detail subsequently, the assistance system 170, in various embodiments, is implemented partially within the vehicle 100, partially on a remote computing device (e.g., a server), and completely on the remote computing device. For example, in one approach, functionality associated with at least one module of the assistance system 170 is implemented within the vehicle 100 while further functionality is implemented within a cloud-based computing system.

With reference to FIG. 2, one embodiment of the assistance system 170 of FIG. 1 is further illustrated. The assistance system 170 is shown as including a processor(s) 110 from the vehicle 100 of FIG. 1. Accordingly, the processor(s) 110 may be a part of the assistance system 170, the assistance system 170 may include a separate processor from the processor(s) 110 of the vehicle 100, or the assistance system 170 may access the processor(s) 110 through a data bus or another communication path. In one embodiment, the assistance system 170 includes a memory 210 that stores a recorder module 220. The memory 210 is a random-access memory (RAM), a read-only memory (ROM), a hard-disk drive, a flash memory, or other suitable memory for storing the recorder module 220. The recorder module 220 is, for example, computer-readable instructions that when executed by the processor(s) 110 cause the processor(s) 110 to perform the various functions disclosed herein.

The assistance system 170 as illustrated in FIG. 2 is generally an abstracted form. Furthermore, the recorder module 220 generally includes instructions that function to control the processor(s) 110 to receive data inputs from one or more sensors of the vehicle 100. The inputs are, in one embodiment, observations of one or more objects in an environment proximate to the vehicle 100 and/or other aspects about the surroundings. As provided for herein, the assistance system 170 and/or the recorder module 220, in one embodiment, acquire the sensor data 250 that includes at least camera images. In further arrangements, the recorder module 220 acquires the sensor data 250 from further sensors such as radar sensors 123, LIDAR sensors 124, and other sensors as may be suitable for identifying vehicles and locations of the vehicles.

Accordingly, the assistance system 170 and/or the recorder module 220, in one embodiment, control the respective sensors to provide the data inputs in the form of the sensor data 250. Additionally, while the assistance system 170 is discussed as controlling the various sensors to provide the sensor data 250, in one or more embodiments, the assistance system 170 can employ other techniques to acquire the sensor data 250 that are either active or passive. For example, the assistance system 170 passively sniffs the sensor data 250 from a stream of electronic information provided by the various sensors to further components within the vehicle 100. Moreover, the assistance system 170 can undertake various approaches to fuse data from multiple sensors when providing the sensor data 250 and/or from sensor data acquired over a wireless communication link. Thus, the sensor data 250, in one embodiment, represents a combination of perceptions acquired from multiple sensors.

Moreover, in one embodiment, the assistance system 170 includes a data store 230 such as a database. The database is, in one embodiment, an electronic data structure stored in the memory 210 or another data store and that is configured with routines that can be executed by the processor(s) 110 for analyzing stored data, providing stored data, organizing stored data, and so on. Thus, in one embodiment, the data store 230 stores data used by the recorder module 220 in executing various functions. In one embodiment, the data store 230 includes the sensor data 250 along with, for example, metadata that characterize various aspects of the sensor data 250. For example, the metadata can include location coordinates (e.g., longitude and latitude), relative map coordinates or tile identifiers, time/date stamps from when the separate sensor data 250 was generated, and so on. In one embodiment, the data store 230 further includes a driving command 240 representing one of a steering command, a braking command, and an acceleration command.

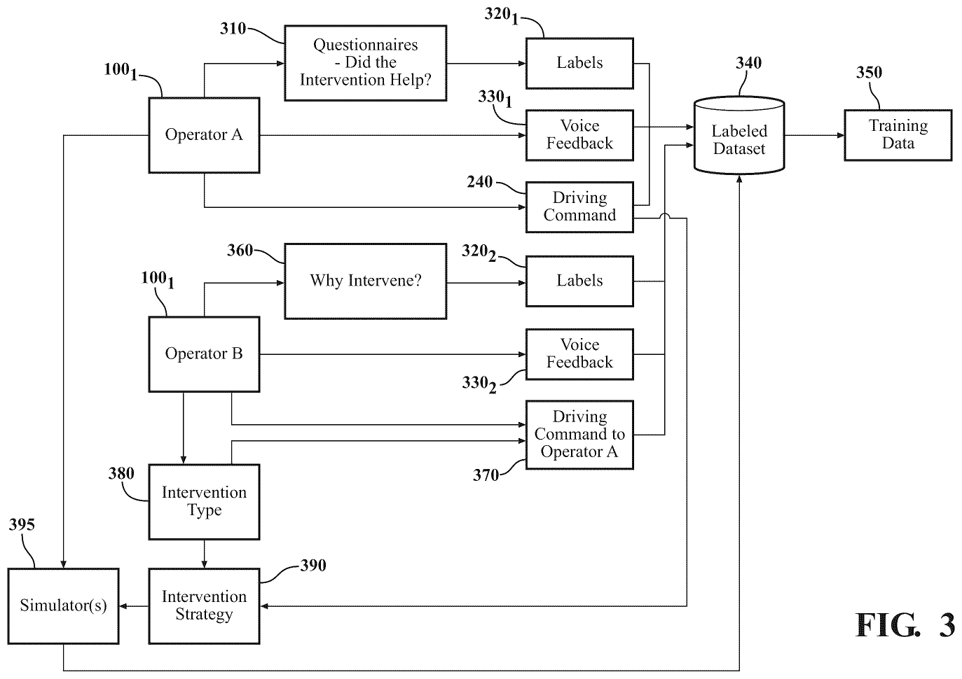

Now turning to FIG. 3, one embodiment of the assistance system 170 having an assisting operator suppling a driving suggestion for a vehicle to follow and generating a labeled dataset is illustrated. Although FIG. 3 illustrates generating training data when supplying a driving suggestion for a vehicle task, the assistance system 170 can automatically generate the labeled dataset for scenarios involving an automated task, a partially automated task, etc., involving suggested inputs between actors. In one approach, the assistance system 170 includes instructions that cause the processor 110 for a remote computing device (e.g., a server) to acquire a driving suggestion from an assisting operator associated with a driving scenario involving the vehicle 100₁. Here, the driving suggestion can be one of a steering command, a braking command, an acceleration command, a voice command, and a labeled explanation about a maneuver during the driving scenario. The remote computing device also receives a driving command and vocal data from the vehicle 100₁ about following the driving suggestion during the driving scenario. The vocal data and the driving command may represent reactions and feedback to the driving suggestion by an operator, another robot, etc. In another approach, a learning model (e.g., a shared-driving model) trains using the driving suggestion, the driving command, and the vocal data. In this way, the learning model training on a server, remote computing device, etc., has robust and complete training data about vast interactions between actors associated with a task.

Moreover, the learning model can be one of a model prediction control (MPC) system, a data-driven system that is trained, an ADS, a shared-decision making (SDM) model, a neural network (NN), and a learning model using a factorization machine (FM). In another approach, the learning model is a convolutional neural network (CNN) that performs semantic segmentation over the sensor data 250 from which further information is derived. Of course, in further aspects, the learning model can employ different machine learning algorithms or implements different approaches for performing the associated functions, which can include deep convolutional encoder-decoder architectures, or another suitable approach that generates semantic labels for the separate object classes represented in driving data. Whichever particular approach, the learning model provides outputs semantic labels identifying qualities represented in the sensor data 250 associated with a task involving multiple robotic devices.

The embodiment in FIG. 3 encompasses an Operator B assisting an Operator A with a task through communicating suggestions. The task can involve assisting a human, humanoid, robot, etc., with executing a task although the example describes a vehicle task. The vehicle 100₁ is one of a simulated vehicle, an online vehicle, a driving simulator, a test vehicle, a field vehicle, and a virtual vehicle. For example, the Operators A and B are running one of the same CARLA session for simulating automated driving and a compact driving simulator (CompactSim) on the vehicle 100₁. In one approach, the Operators A and B are humans and co-located at the vehicle 100₁. For instance, the Operator B is a parent instructing a child represented by the Operator A to drive on a highway while the assistance system 170 captures and labels training data automatically. In one embodiment, Operator A represents a vehicle operator from a typical population. The Operator B may be from one of the typical population and an expert population for generating labeled data during a driving scenario where Operator A follows a driving suggestion. A learning model training with labeled data having a driving suggestion from a typical vehicle operator reflects a real-world operational design domain (ODD) for executing tasks (e.g., automated driving) safely and efficiently. The learning model training with labeled data formatting and identifying the driving suggestion from an expert vehicle operator incorporates an expert bias for purpose-built applications (e.g., racing).

In another embodiment, the Operator B is remote from the Operator A and generates the driving suggestion through a vehicle environment that is virtual and mimics the driving scenario being experienced by the Operator A. The Operators A and B or Operator B can also be a robot that coordinate for executing a task. For instance, a learning model that controls robotic motion for moving furniture trains using data labeled while humans and/or other robots cooperate while moving an object.

In FIG. 3A, the Operator B supplies a multi-modal suggestion for executing a targeted task to Operator A that can include text, voice, a driving command, etc. Examples of the targeted task can be the vehicle 100₁ merging on a road, passing another vehicle, using a left lane for passing a traffic jam in a right lane, driving on a racetrack, etc. The multi-modal suggestion can help the Operator A with the handling and safety of the vehicle 100₁ during the targeted task. Here, labels 320₂ can represent answers to a questionnaire 360 about a driving suggestion communicated to Operator A. The questionnaire 360 can reflect an intervention strategy and goals for Operator A. Furthermore, voice feedback 330₂ and/or driving command 370 may be other driving suggestions communicated by the assistance system 170 during a scenario in real-time. For instance, the Operator B suggests at a time step during a driving scenario executing a braking command followed by a steering command and an acceleration command for vehicle 100₁ to pass another vehicle as the driving command 370. Here, an accompanying voice feedback 330₂ can be “after the next few intersections brake, steer left, and gain speed for overtaking the vehicle ahead at turn six” in one embodiment. In one approach, a large language model (LLM) trains to communicate the driving command 370 verbally. As such, the assistance system 170 can generate commands “Brake now!,” “Accelerate now!,” etc., adaptively using the LLM as the driving scenario evolves. Accordingly, the LLM can generate the driving suggestion to navigate a maneuver using a steering command and a pedal command that are verbal.

The Operator A can incorporate the driving suggestion into the driving scenario completely, in-part, etc. The assistance system 170 acquires labels 320₁ representing answers to a questionnaire 310 about the driving suggestion communicated to Operator A. This can also include acquiring a driving command by the Operator B atop driving commands by the Operator A. The questionnaire 310 can capture a qualitative metric to determine whether the driving suggestion was helpful and understand the purpose of driving actions taken by the Operator A. The questionnaire 310 can also capture the Operator B verbalizing actions after an event, actions that jarred the Operator A, etc. Furthermore, the driving command 240 reflects inputs received by the vehicle 100₁ from the Operator A responsive to the driving suggestion. This can include the driving command 240 being a blend of a driving command from the Operator A and one of a steering command, a braking command, and an accelerator command associated with the driving suggestion from the Operator B. In this way, the training data 350 can derive various real-world interactions between the Operators A and B.

In various implementations, the recorder module 220 captures reactions to the driving suggestion within the training data 350 automatically from labeled dataset 340. This includes labeling without annotation (e.g., manual annotation, manual feedback) and post-processing. The assistance system 170 can generate the labeled dataset 340 and the training data 350 automatically since the data formats for input/outputs about a task are structured and constant. The assistance system 170 having inputs and direction from the Operator B assisting the Operator A also naturally embeds supervision into the labeled dataset 340, thereby improving the training of a learning model. Here, the reactions can include the labels 320₁, the voice feedback 330₁, and the driving command 240 for assembling the labeled dataset 340 representing a real-world state during a driving scenario. For instance, the voice feedback 330₁ captures tones, words, and phrases made by the Operator A before and after the receiving the voice feedback 330₂ and the driving command 370 that expands insights for the labeled dataset 340. As previously explained, the labeled dataset 340 can include tokens (e.g., text, image segments, etc.) having categories (e.g., driving actions) that are timestamped as labels. The learning model can reliably identify patterns and relationships during training using the training data 350 derived from the labeled dataset 340 and output predictions with increased accuracy during inference. This can involve adjusting parameters of the learning model according to design goals. For instance, a design goal is minimizing a loss between a predicted value and an actual value for a task (e.g., a braking command).

Moreover, the recorder module 220 can capture the labels 320₂, the voice feedback 330₂, and the driving command 370 to Operator A within the labeled dataset 340. As such, the assistance system 170 derives the training data 350 for a learning model from the labeled dataset 340 that reflects actual interactions between operators rather than simulated actors, thereby exhibiting reduced noise and accurate in-domain qualities. The assistance system 170 mimicking actual interactions using a driving suggestion also increases flexibility for inter-domain applications. For instance, an assisting operator helping another with a cruising maneuver while controlling a train has vocal interactions that are transferable to driving. In this way, the assistance system 170 reduces computational costs from transferring and adapting a trained learning model between operating domains that are disparate.

Another example involving the assistance system 170 in FIG. 3 is the Operator A driving the vehicle 100₁ normally on the road with the Operator B. The intervention type 380 can involve Operator B manual/automatically selecting assisting approaches that include one of a passive command (e.g., voice feedback), a mixed command, and a complete command for forming the intervention strategy 390. The assistance system 170 communicates a label (e.g., tokens) associated with the intervention type 380 and the intervention strategy 390 for training a learning model with limited supervision, manual feedback, etc.

As previously described, the assistance system 170 can implement the intervention strategy 390 in a driving simulator(s) 395 and/or live on a road for the vehicle 100₁. For instance, the Operator A feeds feedback to the simulator(s) 395 during a maneuver before execution and the simulator(s) 395 feeds the labeled data to the labeled dataset 340. In one approach, the Operator B perturbs the vehicle 100₁ with a steering wheel and a pedal command through offering the Operator A with assistance involving a driving decision as the intervention strategy 390. This can include feeling steering action, pedal action, etc., from the Operator B to the Operator A using actuator feedback (e.g., haptic feedback). The assistance can improve decisions for a driving scenario, encourage the Operator B to make a new decision, etc.

Moreover, the assistance system 170 and one or more vehicle systems 140 can mix the driving command 370 with inputs from the Operator A for generating the driving command 240 using a blending model (e.g., linear blending). This approach can form the intervention strategy 390. For example, the Operator B presses a button that triggers blending a driving command from the Operator B with the Operator A using (1) the blending model without haptics; (2) providing haptic feedback to the Operator A; and/or (3) overriding actions by the Operator A. This blending can be accompanied with verbal feedback to the Operator A as further guidance. In another embodiment, steering commands from the Operator A blend with steering commands and button presses (e.g., a horn sound) of the Operator B for forming the driving command 240 involving a driving scenario. Similarly, a pedal command from the Operator A blends with a pedal command from the Operator B. In this way, the labeled dataset 340 and the training data 350 have Operator A involved with mixed driving rather than fully automated driving that improves training a learning model through having driving interactions that are diverse.

Regarding the complete command, the assistance system 170 can control the vehicle 100₁ using a driving suggestion directly during a time step associated with a maneuver. In one approach, intervention type 380 can control the vehicle 100₁ through communicating the driving command 240, feedback (e.g., haptic feedback), etc., as the driving suggestion. This approach can include indicating a strength of the driving command 240, feedback, etc. For instance, the Operator B increases haptic feedback on a steering wheel for the vehicle 100₁ that improves handling on an upcoming road curve, thereby increasing performance and safety. The haptic feedback can nudge the steering wheel when the Operator A is traveling straight while approaching the upcoming road curve. In another example, upon an operator of the vehicle resisting the driving suggestion with a steering command, the Operator B increases a strength value for haptic feedback corresponding with the driving suggestion and complete command for the maneuver. This example can include the Operator A overriding one of the haptic feedback and the driving suggestion, such as for safety. Therefore, the training data 350 can include various intervention forms and degrees involving the driving command 370 for improving robustness of the learning model during training.

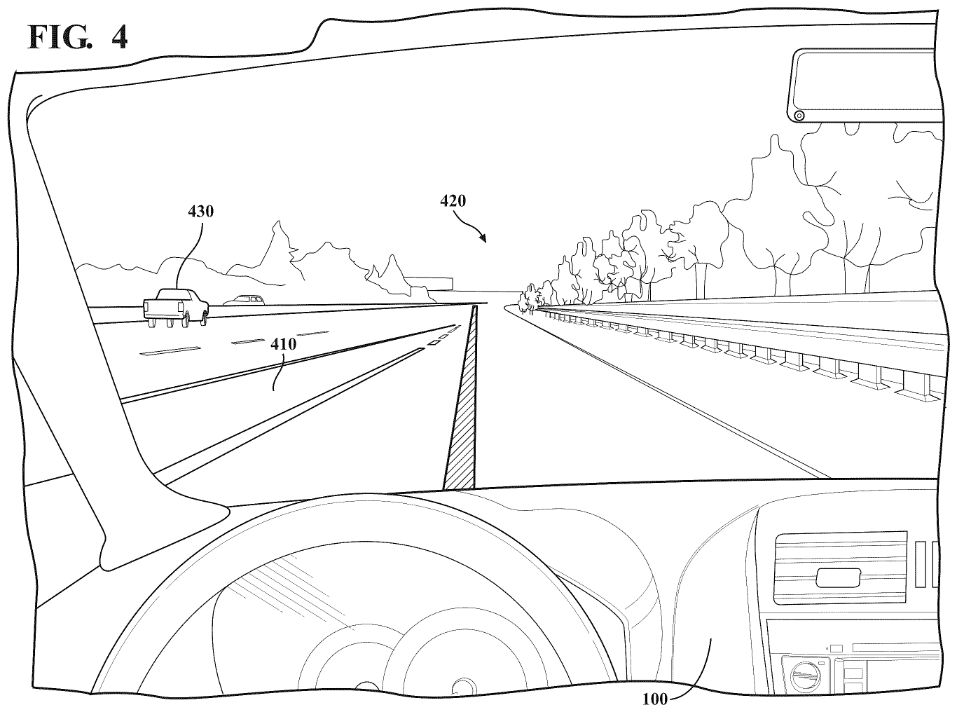

Now turning to FIG. 4, an example of the assistance system 170 implemented in a driving simulator for generating a labeled dataset involving an assisting operator is illustrated. The vehicle 100 can be a simulated vehicle traveling on a road 410 within a driving environment 420. The road 410 includes the pick-up truck 430. Here, an assisting operator can supply a multi-modal suggestion for executing a task to the vehicle 100. The multi-modal suggestion can include text, voice, a driving command, etc. In one approach, the task is the vehicle 100 merging, passing the pick-up truck 430, using a left lane for passing a traffic jam in a right lane, etc. The multi-modal suggestion can help an operator of the vehicle 100 to directly, indirectly, etc., handle the task safely. For instance, the assisting operator suggests at a time step for a driving scenario an acceleration command followed by a steering command for vehicle 100 to the pick-up truck 430. In one embodiment, voice feedback explains the acceleration command and the steering command. Operator A incorporates the multi-modal suggestion into the driving scenario completely, in-part, etc. Meanwhile, the assistance system 170 captures, timestamps, and labels data describing the interaction between the assisting vehicle and the vehicle 100 for training a learning model. In this way, accuracy and awareness about diverse tasks increase while training the learning model due to the labeled data reflecting interactions between human-to-human, human-to-robot, etc., tasks.

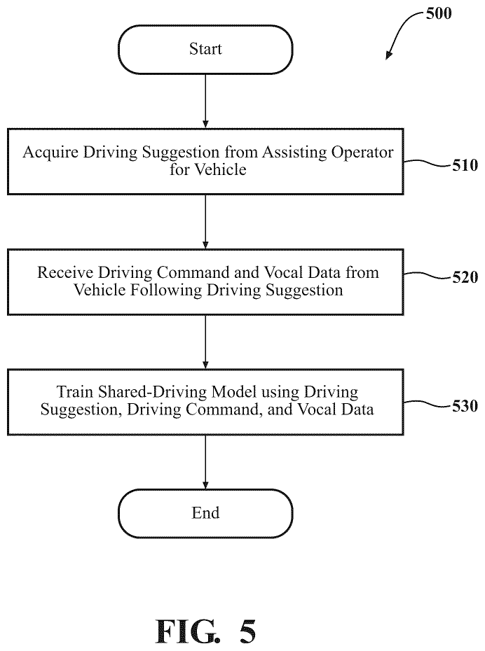

Concerning FIG. 5, one embodiment of a method that is associated with training a shared-driving model using a driving suggestion, a driving command, and vocal data captured by a labeled dataset is illustrated. Method 500 will be discussed from the perspective of the assistance system 170 of FIGS. 1 and 2. While the method 500 is discussed in combination with the assistance system 170, it should be appreciated that the method 500 is not limited to being implemented within the assistance system 170 but is instead one example of a system that may implement the method 500.

At 510, the assistance system 170 acquires a driving suggestion from an assisting operator for an operator of the vehicle 100. The driving suggestion can be one of a steering command, a braking command, an acceleration command, a voice command, passive feedback, active feedback (e.g., haptic feedback), and a labeled explanation. The driving suggestion can be associated with a maneuver during a driving scenario recorded using the recorder module 220.

In one approach, the assistance system 170 operates in-part on a remote computing device (e.g., a server) that requests and acquires the driving suggestion as labeled data for training a learning model (e.g., online training, offline training, etc.). Furthermore, the labeled data reflects an operator reaction to the driving suggestion from the assisting operator that improves training by understanding and observing real-world interactions efficiently. The labeled data has structure and formatting that reduces manual tasks during training, thereby reducing design costs.

At 520, the assistance system 170 receives the driving command 240 and vocal data from the vehicle 100 following the driving suggestion. The driving command 240 can represent one of a steering command, a braking command, and an acceleration command. As previously explained, the driving command 240 reflects inputs received by the vehicle 100 from responding to the driving suggestion. In one approach, the driving command 240 is a blend of inputs from an operator and the driving suggestion from the assisting operator. Furthermore, the voice data can be feedback capturing tones, words, and phrases made by the operator before and after receiving the driving suggestion for expanding insights and breadth of the labeled dataset.

Moreover, the assistance system 170 forms training data from the labeled dataset having the driving suggestion, the driving command, and the vocal data. The labeled dataset can include tokens (e.g., text, image segments, etc.) having categories as labels. As previously explained, a learning model can train by understanding relationships and patterns using the tokens and the labels. In particular, the assistance system 170 automatically labels interactions between the operator and the assisting operator without additional processing (e.g., annotation, manual annotation, manual feedback, etc.) since data formats for input/outputs about a task are structured and constant. The assistance system 170 incorporating inputs and direction from the assisting operator also improves training performance through naturally embedding supervision into the labeled dataset.

At 530, the assistance system 170 trains a shared-driving model using the driving suggestion, the driving command, and the vocal data forming training data from the labeled dataset. Here, the shared-driving model can be one of a MPC system, a data-driven system that is trained, an ADS, a SDM model, a neural network NN, and a learning model using a FM having parameters adjusted during training. For example, a parameter adjusts to minimize a loss between a predicted value made with the training data and an actual value for a task (e.g., a braking command). The learning model has improved training performance as the training data reflects actual interactions between operators rather than simulated operators. The actual interactions also exhibit reduced noise and accurate in-domain qualities. As previously explained, the assistance system 170 mimicking actual interactions using a driving suggestion also increases porting and flexibility of the learning model for inter-domain applications. Accordingly, the assistance system 170 improves training robustness and reduces processing associated with adapting a trained learning model between operating domains using training data generated from interactions involving an assisting operator helping another operator.

FIG. 1 will now be discussed in full detail as an example environment within which the system and methods disclosed herein may operate. In some instances, the vehicle 100 is configured to switch selectively between different modes of operation/control according to the direction of one or more modules/systems of the vehicle 100. In one approach, the modes include: 0, no automation; 1, driver assistance; 2, partial automation; 3, conditional automation; 4, high automation; and 5, full automation. In one or more arrangements, the vehicle 100 can be configured to operate in a subset of possible modes.

In one or more embodiments, the vehicle 100 is an automated or autonomous vehicle. As used herein, “autonomous vehicle” refers to a vehicle that is capable of operating in an autonomous mode (e.g., category 5, full automation). “Automated mode” or “autonomous mode” refers to navigating and/or maneuvering the vehicle 100 along a travel route using one or more computing systems to control the vehicle 100 with minimal or no input from a human driver. In one or more embodiments, the vehicle 100 is highly automated or completely automated. In one embodiment, the vehicle 100 is configured with one or more semi-autonomous operational modes in which one or more computing systems perform a portion of the navigation and/or maneuvering of the vehicle along a travel route, and a vehicle operator (i.e., driver) provides inputs to the vehicle to perform a portion of the navigation and/or maneuvering of the vehicle 100 along a travel route.

The vehicle 100 can include one or more processors 110. In one or more arrangements, the processor(s) 110 can be a main processor of the vehicle 100. For instance, the processor(s) 110 can be an electronic control unit (ECU), an application-specific integrated circuit (ASIC), a microprocessor, etc. The vehicle 100 can include one or more data stores 115 for storing one or more types of data. The data store(s) 115 can include volatile and/or non-volatile memory. Examples of suitable data stores 115 include RAM, flash memory, ROM, programmable read-only memory (PROM), erasable programmable read-only memory (EPROM), electrically erasable programmable read-only memory (EEPROM), registers, magnetic disks, optical disks, and hard drives. The data store(s) 115 can be a component of the processor(s) 110, or the data store(s) 115 can be operatively connected to the processor(s) 110 for use thereby. The term “operatively connected,” as used throughout this description, can include direct or indirect connections, including connections without direct physical contact.

In one or more arrangements, the one or more data stores 115 can include map data 116. The map data 116 can include maps of one or more geographic areas. In some instances, the map data 116 can include information or data on roads, traffic control devices, road markings, structures, features, and/or landmarks in the one or more geographic areas. The map data 116 can be in any suitable form. In some instances, the map data 116 can include aerial views of an area. In some instances, the map data 116 can include ground views of an area, including 360-degree ground views. The map data 116 can include measurements, dimensions, distances, and/or information for one or more items included in the map data 116 and/or relative to other items included in the map data 116. The map data 116 can include a digital map with information about road geometry.

In one or more arrangements, the map data 116 can include one or more terrain maps 117. The terrain map(s) 117 can include information about the terrain, roads, surfaces, and/or other features of one or more geographic areas. The terrain map(s) 117 can include elevation data in the one or more geographic areas. The terrain map(s) 117 can define one or more ground surfaces, which can include paved roads, unpaved roads, land, and other things that define a ground surface.

In one or more arrangements, the map data 116 can include one or more static obstacle maps 118. The static obstacle map(s) 118 can include information about one or more static obstacles located within one or more geographic areas. A “static obstacle” is a physical object whose position does not change or substantially change over a period of time and/or whose size does not change or substantially change over a period of time. Examples of static obstacles can include trees, buildings, curbs, fences, railings, medians, utility poles, statues, monuments, signs, benches, furniture, mailboxes, large rocks, or hills. The static obstacles can be objects that extend above ground level. The one or more static obstacles included in the static obstacle map(s) 118 can have location data, size data, dimension data, material data, and/or other data associated with it. The static obstacle map(s) 118 can include measurements, dimensions, distances, and/or information for one or more static obstacles. The static obstacle map(s) 118 can be high quality and/or highly detailed. The static obstacle map(s) 118 can be updated to reflect changes within a mapped area.

One or more data stores 115 can include sensor data 119. In this context, “sensor data” means any information about the sensors that the vehicle 100 is equipped with, including the capabilities and other information about such sensors. As will be explained below, the vehicle 100 can include the sensor system 120. The sensor data 119 can relate to one or more sensors of the sensor system 120. As an example, in one or more arrangements, the sensor data 119 can include information about one or more LIDAR sensors 124 of the sensor system 120.

In some instances, at least a portion of the map data 116 and/or the sensor data 119 can be located in one or more data stores 115 located onboard the vehicle 100. Alternatively, or in addition, at least a portion of the map data 116 and/or the sensor data 119 can be located in one or more data stores 115 that are located remotely from the vehicle 100.

As noted above, the vehicle 100 can include the sensor system 120. The sensor system 120 can include one or more sensors. “Sensor” means a device that can detect, and/or sense something. In at least one embodiment, the one or more sensors detect, and/or sense in real-time. As used herein, the term “real-time” means a level of processing responsiveness that a user or system senses as sufficiently immediate for a particular process or determination to be made, or that enables the processor to keep up with some external process.

In arrangements in which the sensor system 120 includes a plurality of sensors, the sensors may function independently or two or more of the sensors may function in combination. The sensor system 120 and/or the one or more sensors can be operatively connected to the processor(s) 110, the data store(s) 115, and/or another element of the vehicle 100. The sensor system 120 can produce observations about a portion of the environment of the vehicle 100 (e.g., nearby vehicles).

The sensor system 120 can include any suitable type of sensor. Various examples of different types of sensors will be described herein. However, it will be understood that the embodiments are not limited to the particular sensors described. The sensor system 120 can include one or more vehicle sensors 121. The vehicle sensor(s) 121 can detect information about the vehicle 100 itself. In one or more arrangements, the vehicle sensor(s) 121 can be configured to detect position and orientation changes of the vehicle 100, such as, for example, based on inertial acceleration. In one or more arrangements, the vehicle sensor(s) 121 can include one or more accelerometers, one or more gyroscopes, an inertial measurement unit (IMU), a dead-reckoning system, a global navigation satellite system (GNSS), a global positioning system (GPS), a navigation system 147, and/or other suitable sensors. The vehicle sensor(s) 121 can be configured to detect one or more characteristics of the vehicle 100 and/or a manner in which the vehicle 100 is operating. In one or more arrangements, the vehicle sensor(s) 121 can include a speedometer to determine a current speed of the vehicle 100.

Alternatively, or in addition, the sensor system 120 can include one or more environment sensors 122 configured to acquire data about an environment surrounding the vehicle 100 in which the vehicle 100 is operating. “Surrounding environment data” includes data about the external environment in which the vehicle is located or one or more portions thereof. For example, the one or more environment sensors 122 can be configured to sense obstacles in at least a portion of the external environment of the vehicle 100 and/or data about such obstacles. Such obstacles may be stationary objects and/or dynamic objects. The one or more environment sensors 122 can be configured to detect other things in the external environment of the vehicle 100, such as, for example, lane markers, signs, traffic lights, traffic signs, lane lines, crosswalks, curbs proximate to the vehicle 100, off-road objects, etc.

Various examples of sensors of the sensor system 120 will be described herein. The example sensors may be part of the one or more environment sensors 122 and/or the one or more vehicle sensors 121. However, it will be understood that the embodiments are not limited to the particular sensors described.

As an example, in one or more arrangements, the sensor system 120 can include one or more of: radar sensors 123, LIDAR sensors 124, sonar sensors 125, weather sensors, haptic sensors, locational sensors, and/or one or more cameras 126. In one or more arrangements, the one or more cameras 126 can be high dynamic range (HDR) cameras, stereo, or infrared (IR) cameras.

The vehicle 100 can include an input system 130. An “input system” includes components or arrangement or groups thereof that enable various entities to enter data into a machine. The input system 130 can receive an input from a vehicle occupant. The vehicle 100 can include an output system 135. An “output system” includes one or more components that facilitate presenting data to a vehicle occupant.

The vehicle 100 can include the one or more vehicle systems 140. Various examples of the one or more vehicle systems 140 are shown in FIG. 1. However, the vehicle 100 can include more, fewer, or different vehicle systems. It should be appreciated that although particular vehicle systems are separately defined, any of the systems or portions thereof may be otherwise combined or segregated via hardware and/or software within the vehicle 100. The vehicle 100 can include a propulsion system 141, a braking system 142, a steering system 143, a throttle system 144, a transmission system 145, a signaling system 146, and/or a navigation system 147. Any of these systems can include one or more devices, components, and/or a combination thereof, now known or later developed.

The navigation system 147 can include one or more devices, applications, and/or combinations thereof, now known or later developed, configured to determine the geographic location of the vehicle 100 and/or to determine a travel route for the vehicle 100. The navigation system 147 can include one or more mapping applications to determine a travel route for the vehicle 100. The navigation system 147 can include a global positioning system, a local positioning system, or a geolocation system.

The processor(s) 110, the assistance system 170, and/or the automated driving module(s) 160 can be operatively connected to communicate with the various vehicle systems 140 and/or individual components thereof. For example, the processor(s) 110 and/or the automated driving module(s) 160 can be in communication to send and/or receive information from the various vehicle systems 140 to control the movement of the vehicle 100. The processor(s) 110, the assistance system 170, and/or the automated driving module(s) 160 may control some or all of the vehicle systems 140 and, thus, may be partially or fully autonomous as defined by the society of automotive engineers (SAE) levels 0 to 5.

The processor(s) 110, the assistance system 170, and/or the automated driving module(s) 160 can be operatively connected to communicate with the various vehicle systems 140 and/or individual components thereof. For example, the processor(s) 110, the assistance system 170, and/or the automated driving module(s) 160 can be in communication to send and/or receive information from the various vehicle systems 140 to control the movement of the vehicle 100. The processor(s) 110, the assistance system 170, and/or the automated driving module(s) 160 may control some or all of the vehicle systems 140.

The processor(s) 110, the assistance system 170, and/or the automated driving module(s) 160 may be operable to control the navigation and maneuvering of the vehicle 100 by controlling one or more of the vehicle systems 140 and/or components thereof. For instance, when operating in an autonomous mode, the processor(s) 110, the assistance system 170, and/or the automated driving module(s) 160 can control the direction and/or speed of the vehicle 100. The processor(s) 110, the assistance system 170, and/or the automated driving module(s) 160 can cause the vehicle 100 to accelerate, decelerate, and/or change direction. As used herein, “cause” or “causing” means to make, force, compel, direct, command, instruct, and/or enable an event or action to occur or at least be in a state where such event or action may occur, either in a direct or indirect manner.

The vehicle 100 can include one or more actuators 150. The actuators 150 can be an element or a combination of elements operable to alter one or more of the vehicle systems 140 or components thereof responsive to receiving signals or other inputs from the processor(s) 110 and/or the automated driving module(s) 160. For instance, the one or more actuators 150 can include motors, pneumatic actuators, hydraulic pistons, relays, solenoids, and/or piezoelectric actuators, just to name a few possibilities.

The vehicle 100 can include one or more modules, at least some of which are described herein. The modules can be implemented as computer-readable program code that, when executed by a processor(s) 110, implement one or more of the various processes described herein. One or more of the modules can be a component of the processor(s) 110, or one or more of the modules can be executed on and/or distributed among other processing systems to which the processor(s) 110 is operatively connected. The modules can include instructions (e.g., program logic) executable by one or more processors 110. Alternatively, or in addition, one or more data stores 115 may contain such instructions.

In one or more arrangements, one or more of the modules described herein can include artificial intelligence elements, e.g., neural network, fuzzy logic, or other machine learning algorithms. Furthermore, in one or more arrangements, one or more of the modules can be distributed among a plurality of the modules described herein. In one or more arrangements, two or more of the modules described herein can be combined into a single module.

The vehicle 100 can include one or more automated driving modules 160. The automated driving module(s) 160 can be configured to receive data from the sensor system 120 and/or any other type of system capable of capturing information relating to the vehicle 100 and/or the external environment of the vehicle 100. In one or more arrangements, the automated driving module(s) 160 can use such data to generate one or more driving scene models. The automated driving module(s) 160 can determine position and velocity of the vehicle 100. The automated driving module(s) 160 can determine the location of obstacles, obstacles, or other environmental features including traffic signs, trees, shrubs, neighboring vehicles, pedestrians, etc.

The automated driving module(s) 160 can be configured to receive, and/or determine location information for obstacles within the external environment of the vehicle 100 for use by the processor(s) 110, and/or one or more of the modules described herein to estimate position and orientation of the vehicle 100, vehicle position in global coordinates based on signals from a plurality of satellites, or any other data and/or signals that could be used to determine the current state of the vehicle 100 or determine the position of the vehicle 100 with respect to its environment for use in either creating a map or determining the position of the vehicle 100 in respect to map data.

The automated driving module(s) 160 either independently or in combination with the assistance system 170 can be configured to determine travel path(s), current autonomous driving maneuvers for the vehicle 100, future autonomous driving maneuvers and/or modifications to current autonomous driving maneuvers based on data acquired by the sensor system 120, driving scene models, and/or data from any other suitable source such as determinations from the sensor data 250. “Driving maneuver” means one or more actions that affect the movement of a vehicle. Examples of driving maneuvers include: accelerating, decelerating, braking, turning, moving in a lateral direction of the vehicle 100, changing travel lanes, merging into a travel lane, and/or reversing, just to name a few possibilities. The automated driving module(s) 160 can be configured to implement determined driving maneuvers. The automated driving module(s) 160 can cause, directly or indirectly, such autonomous driving maneuvers to be implemented. As used herein, “cause” or “causing” means to make, command, instruct, and/or enable an event or action to occur or at least be in a state where such event or action may occur, either in a direct or indirect manner. The automated driving module(s) 160 can be configured to execute various vehicle functions and/or to transmit data to, receive data from, interact with, and/or control the vehicle 100 or one or more systems thereof (e.g., one or more of vehicle systems 140).

Detailed embodiments are disclosed herein. However, it is to be understood that the disclosed embodiments are intended as examples. Therefore, specific structural and functional details disclosed herein are not to be interpreted as limiting, but merely as a basis for the claims and as a representative basis for teaching one skilled in the art to variously employ the aspects herein in virtually any appropriately detailed structure. Furthermore, the terms and phrases used herein are not intended to be limiting but rather to provide an understandable description of possible implementations. Various embodiments are shown in FIGS. 1-5, but the embodiments are not limited to the illustrated structure or application.

The flowcharts and block diagrams in the figures illustrate the architecture, functionality, and operation of possible implementations of systems, methods, and computer program products according to various embodiments. In this regard, a block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components, and/or processes described above can be realized in hardware or a combination of hardware and software and can be realized in a centralized fashion in one processing system or in a distributed fashion where different elements are spread across several interconnected processing systems. Any kind of processing system or another apparatus adapted for carrying out the methods described herein is suited. A typical combination of hardware and software can be a processing system with computer-usable program code that, when being loaded and executed, controls the processing system such that it carries out the methods described herein.

The systems, components, and/or processes also can be embedded in a computer-readable storage, such as a computer program product or other data programs storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer-readable storage medium would include the following: a portable computer diskette, a hard disk drive (HDD), a solid-state drive (SSD), a ROM, an EPROM or flash memory, a portable compact disc read-only memory (CD-ROM), a digital versatile disc (DVD), an optical storage device, a magnetic storage device, or any suitable combination of the foregoing. In the context of this document, a computer-readable storage medium may be any tangible medium that can contain, or store a program for use by or in connection with an instruction execution system, apparatus, or device.

Generally, modules as used herein include routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an ASIC, a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, radio frequency (RF), etc., or any suitable combination of the foregoing. Computer program code for carrying out operations for aspects of the present arrangements may be written in any combination of one or more programming languages, including an object-oriented programming language such as Java™, Smalltalk™, C++, or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all combinations of one or more of the associated listed items. As an example, the phrase “at least one of A, B, and C” includes A, B, C, or any combination thereof (e.g., AB, AC, BC, or ABC).

Aspects herein can be embodied in other forms without departing from the spirit or essential attributes thereof. Accordingly, reference should be made to the following claims, rather than to the foregoing specification, as indicating the scope hereof.

What is claimed is:

1. An assistance system comprising:
a memory storing instructions that, when executed by a processor, cause the processor to:
acquire a driving suggestion from an assisting operator associated with a driving scenario involving a vehicle;
receive a driving command and vocal data from the vehicle about following the driving suggestion during the driving scenario; and
train a shared-driving model using the driving suggestion, the driving command, and the vocal data.

2. The assistance system of claim 1, wherein the instructions to receive the driving command further include instructions to:
communicate a dataset labeled automatically without manual annotation for feedback about the driving suggestion, the vocal data, and the driving command, and the dataset includes information from a questionnaire about the feedback and the dataset forms training data for the shared-driving model.

3. The assistance system of claim 1 further including instructions to:
control the vehicle using the driving suggestion directly during a time step associated with a maneuver for the driving scenario;
upon an operator of the vehicle resisting the driving suggestion with a steering command, increase a strength value for haptic feedback corresponding with the driving suggestion for the maneuver; and
communicate a label for the steering command and the maneuver without supervision, the label having tokens representing the steering command and the maneuver.

4. The assistance system of claim 3, wherein the operator overrides the haptic feedback and the driving suggestion.

5. The assistance system of claim 1, wherein a large language model (LLM) generates the driving suggestion to navigate a maneuver using a steering command and a pedal command that are verbal.

6. The assistance system of claim 1, wherein the driving command is a blend of an operator command and one of a steering command, a braking command, and an accelerator command associated with the driving suggestion.

7. The assistance system of claim 1, wherein:
the assisting operator is one of co-located and remote from the vehicle;
the assisting operator is one of a human and a robot; and
the vehicle is one of a simulated vehicle, an online vehicle, a driving simulator, a test vehicle, and a field vehicle.

8. The assistance system of claim 1, wherein the shared-driving model is one of a model prediction control (MPC) system, a data-driven system that is trained, an automated driving system (ADS), a shared-decision making (SDM) model, a neural network (NN), and a learning model using a factorization machine (FM).

9. The assistance system of claim 1, wherein:
the driving suggestion is one of a steering command, a braking command, an acceleration command, a voice command, and a labeled explanation about a maneuver during the driving scenario;
the driving command is one of the steering command, the braking command, and the acceleration command;
the vocal data and the driving command represent reactions to the driving suggestion; and
the vehicle is one of an automobile, a simulated vehicle, a virtual vehicle, a train, an airplane, and a boat.

10. A non-transitory computer-readable medium comprising:
instructions that when executed by a processor cause the processor to:
acquire a driving suggestion from an assisting operator associated with a driving scenario involving a vehicle;
receive a driving command and vocal data from the vehicle about following the driving suggestion during the driving scenario; and
train a shared-driving model using the driving suggestion, the driving command, and the vocal data.

11. The non-transitory computer-readable medium of claim 10, wherein the instructions to
receive the driving command further include instructions to:
communicate a dataset labeled automatically without manual annotation for feedback about the driving suggestion, the vocal data, and the driving command, and the dataset includes information from a questionnaire about the feedback and the dataset forms training data for the shared-driving model.

12. A method comprising:
acquiring a driving suggestion from an assisting operator associated with a driving scenario involving a vehicle;
receiving a driving command and vocal data from the vehicle about following the driving suggestion during the driving scenario; and
training a shared-driving model using the driving suggestion, the driving command, and the vocal data.

13. The method of claim 12, wherein receiving the driving command further includes:
communicating a dataset labeled automatically without manual annotation for feedback about the driving suggestion, the vocal data, and the driving command, and the dataset includes information from a questionnaire about the feedback and the dataset forms training data for the shared-driving model.

14. The method of claim 12 further comprising:
controlling the vehicle using the driving suggestion directly during a time step associated with a maneuver for the driving scenario;
upon an operator of the vehicle resisting the driving suggestion with a steering command, increasing a strength value for haptic feedback corresponding with the driving suggestion for the maneuver; and
communicating a label for the steering command and the maneuver without supervision, the label having tokens representing the steering command and the maneuver.

15. The method of claim 14, wherein the operator overrides the haptic feedback and the driving suggestion.

16. The method of claim 12, wherein a large language model (LLM) generates the driving suggestion to navigate a maneuver using a steering command and a pedal command that are verbal.

17. The method of claim 12, wherein the driving command is a blend of an operator command and one of a steering command, a braking command, and an accelerator command associated with the driving suggestion.

18. The method of claim 12, wherein:
the assisting operator is one of co-located and remote from the vehicle;
the assisting operator is one of a human and a robot; and
the vehicle is one of a simulated vehicle, an online vehicle, a driving simulator, a test vehicle, and a field vehicle.

19. The method of claim 12, wherein the shared-driving model is one of a model prediction control (MPC) system, a data-driven system that is trained, an automated driving system (ADS), a shared-decision making (SDM) model, a neural network (NN), and a learning model using a factorization machine (FM).

20. The method of claim 12, wherein:
the driving suggestion is one of a steering command, a braking command, an acceleration command, a voice command, and a labeled explanation about a maneuver during the driving scenario;
the driving command is one of the steering command, the braking command, and the acceleration command;
the vocal data and the driving command represent reactions to the driving suggestion; and
the vehicle is one of an automobile, a simulated vehicle, a virtual vehicle, a train, an airplane, and a boat.
